(19) United States
(12) Patent Application Publication
(10) Pub. No.: US 2012/0152602 A1
(43) Pub. Date: Jun. 21, 2012

(54) PRINTED CIRCUIT BOARD

(75) Inventors: YUNG-CHIEH CHEN, Tu-Cheng (TW); YU-CHANG PAI, Tu-Cheng (TW); DUEN-YI HO, Tu-Cheng (TW); SHOU-KUO HSU, Tu-Cheng (TW)

(73) Assignee: HON HAI PRECISION INDUSTRY CO., LTD., Tu-Cheng (TW)

(21) Appl. No.: 12/981,480

(22) Filed: Dec. 30, 2010

(30) Foreign Application Priority Data
Dec. 15, 2010 (TW) 99143866

(51) Int. Cl. H05K 1/18

(52) U.S. Cl. 174/260

(57) ABSTRACT

A printed circuit board (PCB) includes a top layer, a memory controller, a gap, and a connector. The memory controller is located on the top layer. A number of first golden fingers are set on the top layer near the gap and electrically connected to the memory controller. A connector includes a first slot to hold the first golden fingers and a second slot to hold a number of second golden fingers of a memory chip. The first slot is electrically connected to the second slot. The memory chip and the PCB are coplanar.

### BACKGROUND

1. Technical Field

The present disclosure relates to a printed circuit board (PCB).

2. Description of Related Art

In notebook computers, memory chips are soldered on motherboards to reduce the thickness of the notebook computers. However, for these notebooks with soldered memory chips the memory capacity cannot be changed. In other notebook computers, the memory chips are not soldered onto the motherboard but are inserted into sockets that align the memory chips almost flat with the motherboard. However, the memory chips or slots still increases the height the motherboard will occupy. Therefore there is room for improvement in the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of an exemplary of a printed circuit board.

FIG. 2 is a schematic diagram of a connector of the printed circuit board of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

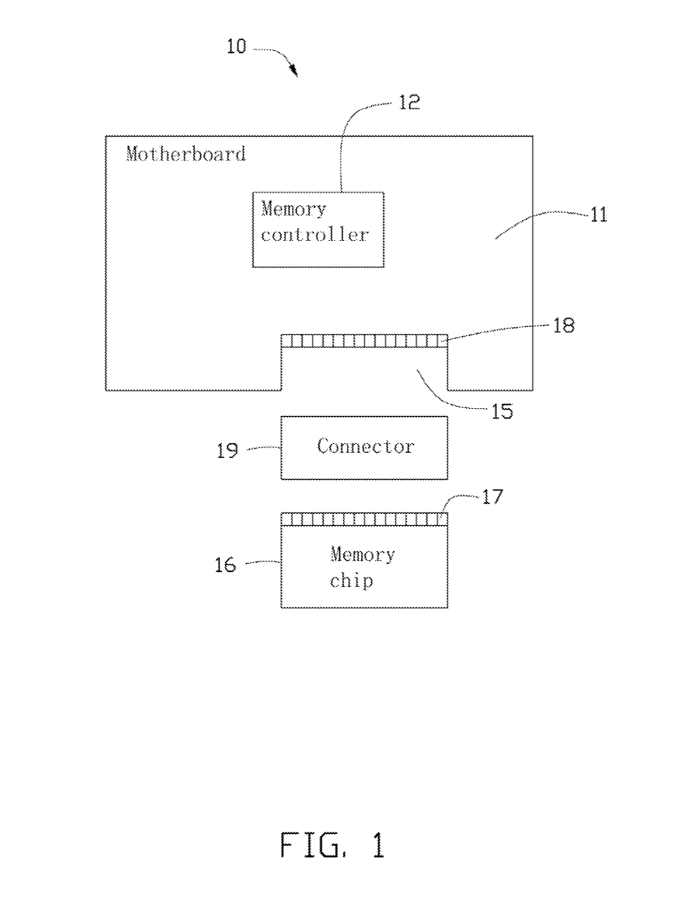

Referring to FIG. 1, an exemplary embodiment of a printed circuit board (PCB) includes a top layer 11 and other layers (not shown). A memory controller 12 is located on the top layer 11. In the embodiment, the PCB is a motherboard 10.

The motherboard 10 defines a gap 15 through the top layer 10 and the other layers. A length of the gap 15 is equal to a length of a memory chip 16. A plurality of golden fingers 18 are set on the motherboard 10 near the gap 15. The golden fingers 18 are electrically connected to the memory controller 12 through traces on the motherboard 10.

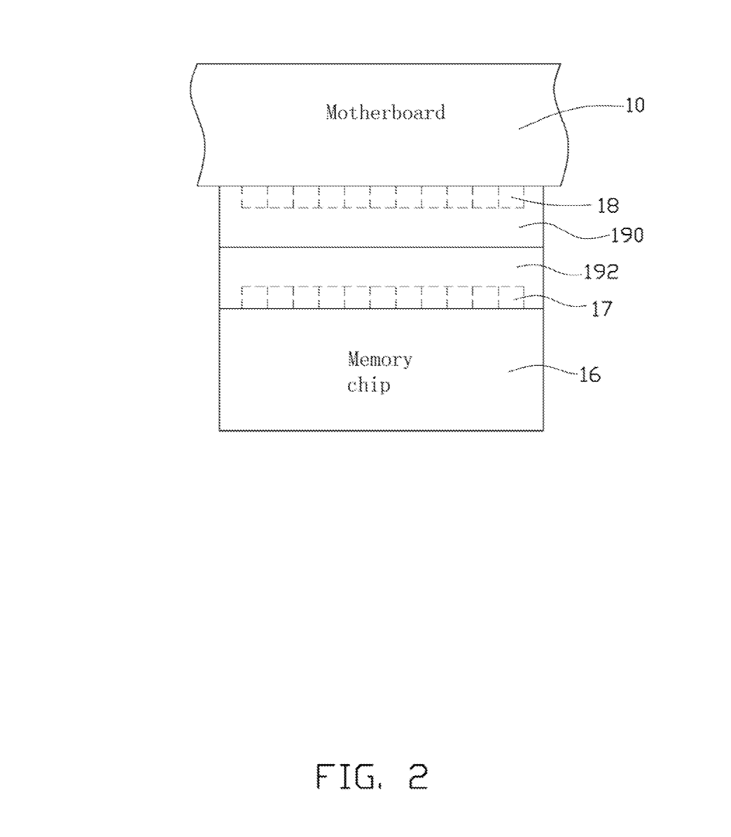

Also referring to FIG. 2, in the embodiment, the connector 19 includes a first memory slot 190 and a second memory slot 192 electrically connected to each other. The first memory slot 190 is configured to hold the golden fingers 18 of the motherboard 10. The second memory slot 192 is configured to hold the golden fingers 17 of the memory chip 16. Because the first memory slot 190 is connected to the second memory slot 192, the memory controller 12 can communicate with the memory chip 16 through the golden fingers 18 and the connector 19. Moreover, when the memory chip 16 is plugged into the second memory slot 192, the memory chip 16 and the motherboard 10 are coplanar. As a result, a thickness of the motherboard 10 including the memory chip 16 is same as the thickness of the motherboard 10. In addition, different memory chips with different capacity can be installed in the motherboard 10.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board (PCB) comprising:
a top layer defining a gap through the PCB, the top layer comprising a plurality of first golden fingers adjacent to the gap;
a memory controller located on the top layer and electrically connected to the plurality of first golden fingers; and
a connector comprising a first slot to hold the plurality of first golden fingers near the gap and a second slot to hold a plurality of second golden fingers of a memory chip, wherein the first slot is electrically connected to the second slot, the memory chip and the PCB are coplanar.

2. The PCB of claim 1, wherein a length of the gap is equal to a length of the memory chip.
